(19) United States
(12) Patent Application Publication
(10) Pub. No.: US 2026/0052707 A1
(43) Pub. Date: Feb. 19, 2026

(54) SEMICONDUCTOR DEVICE AND METHOD FOR FABRICATING THE SAME

(71) Applicant: SK hynix Inc., Gyeonggi-do (KR)

(72) Inventors: Jeong Myeong KIM, Gyeonggi-do (KR); Cha Deok DONG, Gyeonggi-do (KR); Keo Rock CHOI, Gyeonggi-do (KR)

(21) Appl. No.: 19/218,376

(22) Filed: May 26, 2025

(30) Foreign Application Priority Data
Aug. 13, 2024 (KR) 10-2024-0108359

(51) Int. Cl. H10B 63/00; H10N 70/00; H10N 70/20

(52) U.S. Cl. CPC H10B 63/24; H10B 63/22; H10B 63/84; H10N 70/023; H10N 70/043; H10N 70/25; H10N 70/826; H10N 70/884

(57) ABSTRACT

Disclosed are a semiconductor device with improved selector characteristics of memory cells, and a method for fabricating the semiconductor device. A semiconductor device includes a plurality of memory cells wherein each of the memory cells includes a memory layer; a selector layer formed in an upper or lower portion of the memory layer to select the memory layer; and a buffer layer directly coupled to an upper or lower portion of the selector layer, wherein the buffer layer includes an amorphous silicon layer including at least one dopant selected from a group including group-13 elements, group-14 elements, and group-15 elements of the periodic table.

### CROSS-REFERENCE TO RELATED APPLICATIONS

The present application claims priority under 35 U.S.C 119(a) to Korean Patent Application No. 10-2024-0108359, filed on Aug. 13, 2024, which is incorporated herein by reference in its entirety.

### BACKGROUND

### 1. Field

Embodiments of the present invention relate to a semiconductor technology, and more particularly, to a semiconductor device including memory cells with a selector, and a method for fabricating the semiconductor device.

### 2. Description of the Related Art

Recently, semiconductor devices capable of storing data in diverse electronic devices, such as computers and portable communication devices, are demanded to cope with the trends of miniaturization, low power consumption, high performance, and diversification of electronic devices. Researchers and the industry are studying to develop such semiconductor devices. The semiconductor devices capable of storing data by taking advantage of the characteristic of switching between different resistance states according to the applied voltage or current may include a Resistive Random Access Memory (RRAM), a Phase-change Random Access Memory (PRAM), a Ferroelectric Random Access Memory (FRAM), a Magnetic Random Access Memory (MRAM), an e-fuse and the like.

A memory device having a variable resistance element may include a selector as an element for selecting a particular memory cell among a plurality of memory cells that are arrayed, and the selector may be realized as a thin layer in a memory cell.

### SUMMARY

Embodiments of the present disclosure are directed to a semiconductor device with improved selector characteristics of memory cells, and a method for fabricating the semiconductor device.

In accordance with an embodiment of the present disclosure, a semiconductor device includes a plurality of memory cells wherein each of the memory cells includes a memory layer; a selector layer formed in an upper or lower portion of the memory layer to select the memory layer; and a buffer layer directly coupled to an upper or lower portion of the selector layer, and the buffer layer includes an amorphous silicon layer including at least one dopant selected from a group including group-13 elements, group-14 elements, and group-15 elements of the periodic table.

In accordance with another embodiment of the present disclosure, a method for fabricating a semiconductor device including a plurality of memory cells includes forming a selector layer; and forming an amorphous silicon layer including a dopant as a buffer layer in an upper or lower portion of the selector layer, wherein the buffer layer includes an amorphous silicon layer including at least one dopant that is selected from a group including group-13 elements, group-14 elements, and group-15 elements of periodic table.

These and other features and advantages of the embodiments of the present disclosure will become better understood by those with ordinary skill in the art from the following example figures and embodiments.

### BRIEF DESCRIPTION OF THE DRAWINGS

FIGS. 1A and 1B illustrate a semiconductor device in accordance with an embodiment of the present disclosure.

FIG. 2 is a cross-sectional view illustrating a structure of a selector unit SU in accordance with an embodiment of the present disclosure.

FIGS. 3A and 3B illustrate a semiconductor device in accordance with another embodiment of the present disclosure.

FIG. 4 is a cross-sectional view illustrating a structure of a selector unit SU in an off state and in an on state in accordance with an embodiment of the present disclosure.

FIG. 5 illustrates an operation of a selector unit SU in accordance with an embodiment of the present disclosure.

FIGS. 6A to 7D are cross-sectional views illustrating a semiconductor device and a fabrication method thereof in accordance with an embodiment of the present disclosure.

### DETAILED DESCRIPTION

Hereinafter, various embodiments of the present disclosure will be described in detail with reference to the attached drawings.

Embodiments of the present disclosure will be described below in more detail with reference to the accompanying drawings. The embodiments may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

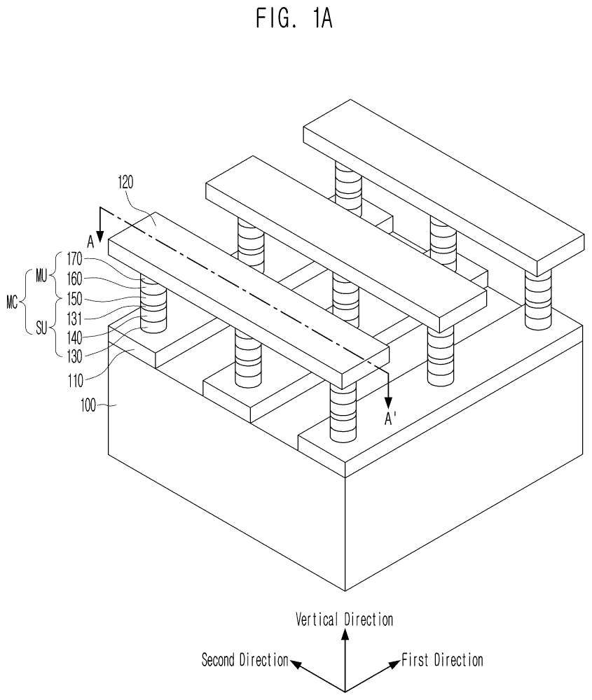

FIGS. 1A and 1B illustrate a semiconductor memory in accordance with an embodiment of the present disclosure. FIG. 1A is a perspective view, and FIG. 1B is a cross-sectional view taken along a line A-A′ shown in FIG. 1A. The semiconductor memory in accordance with the embodiment of the present disclosure may have a structure in which a buffer layer 131 is formed over a selector layer 140.

Referring to FIGS. 1A and 1B, the semiconductor device in accordance with the embodiment of the present disclosure may have a cross-point structure including a substrate 100, a plurality of first conductive lines 110 disposed over the substrate 100 and extending in a first direction, a plurality of second conductive lines 120 disposed over the first conductive lines 110 and extending in a second direction intersecting with the first direction, and a plurality of memory cells MC disposed to overlap with the intersection regions between the first conductive lines 110 and the second conductive lines 120. Here, the first direction and the second direction may mean a direction substantially parallel to the surface of the substrate 100. Hereinafter, a direction substantially perpendicular to the surface of the substrate 100 may be referred to as a vertical direction.

The substrate 100 may include a semiconductor material, such as silicon. Also, a predetermined required lower structure (not shown) may be formed in the substrate 100. For example, an integrated circuit for driving a first conductive line 110 and/or a second conductive line 120 may be formed in the substrate 100.

The first conductive lines 110 may be disposed spaced apart from each other at a regular interval along the second direction. The first conductive lines 110 may include diverse conductive materials, for example, a metal such as platinum (Pt), tungsten (W), aluminum (Al), copper (Cu), tantalum (Ta) and the like, a metal nitride such as titanium nitride (TIN), tantalum nitride (TaN) and the like, or a combination thereof. The first conductive lines 110 may have a single-layer structure or a multi-layer structure.

A plurality of second conductive lines 120 may be disposed spaced apart from each other at a regular interval along the first direction. The second conductive lines 120 may include diverse conductive materials, for example, a metal such as platinum (Pt), tungsten (W), aluminum (Al), copper (Cu), tantalum (Ta) and the like, a metal nitride such as titanium nitride (TIN), tantalum nitride (TaN) and the like, or a combination thereof. The second conductive lines 120 may have a single-layer structure or a multi-layer structure.

Each of the memory cells MC may include a memory unit MU that actually stores data, and a selector unit SU that controls the access to the memory unit MU. Each of the memory cells MC may include a first electrode layer 130 disposed below the selector layer 140, and a second electrode layer 150 and/or a third electrode layer 170 disposed over the selector layer 140. In each memory cell MC, a buffer layer 131 may be disposed between the selector layer 140 and the first electrode layer 130. For example, the memory cell MC may include a stacked structure of the first electrode layer 130, the buffer layer 131, the selector layer 140, the second electrode layer 150, the memory layer 160, and the third electrode layer 170 stacked in the recited order over a corresponding one of the first conductive lines 110. For example, the order of the buffer layer 131 and the selector layer 140 may be switched. The selector unit SU may include the first electrode layer 130, the buffer layer 131, the selector layer 140, and the second electrode layer 150. The memory unit MU may include the second electrode layer 150, the memory layer 160, and the third electrode layer 170. Hence, the second electrode layer 150 may be shared by the selector unit SU and the memory unit MU.

The first electrode layer 130 and the third electrode layer 170 may be respectively disposed at both ends of the memory cell MC, that is, at the bottom end and the top end, and may function to apply a voltage or current that is required for an operation of the memory cell MC. The second electrode layer 150 may function to electrically connect the selector layer 140 and the memory layer 160 to each other while physically separating them from each other. The first electrode layer 130, the second electrode layer 150, or the third electrode layer 170 may include diverse conductive materials, for example, metals such as platinum (Pt), tungsten (W), aluminum (Al), copper (Cu), tantalum (Ta), titanium (Ti) and the like, metal nitrides such as titanium nitride (TiN), tantalum nitride (TaN) and the like, or combinations thereof. Also, the first electrode layer 130, the second electrode layer 150, or the third electrode layer 170 may include a carbon electrode. Each of the memory cells MC may include a SIN thin layer at an interface between the first electrode layer 130 and the selector layer 140, and a carbon (C) thin layer at an interface between the selector layer 140 and the second electrode layer 150.

The memory layer 160 may function to store data in diverse ways. For example, the memory layer 160 may include a variable resistance layer that stores different data by switching between different resistance states according to the voltage or current supplied through the upper and lower ends of the memory layer 160. The variable resistance layer may have a single-layer structure or a multi-layer structure including diverse materials used in a Resistive Random Access Memory (RRAM), a Phase-change Random Access Memory (PRAM), a Ferroelectric Random Access Memory (FRAM), a Magnetic Random Access Memory (MRAM) and the like, for example, metal oxides, such as transition metal oxides, perovskite-based materials and the like, phase-change materials such as chalcogenide-based materials, ferroelectric materials, ferromagnetic materials, and the like.

The selector layer 140 may be formed as a thin layer in the memory cell. A thin layer, as used herein, refers to a layer having a thickness of 1 nm to 100 nm, 1 nm to 50 nm, or 1 nm to 30 nm. The selector layer 140 may have a function of preventing current leakage that may occur between the memory cells MC that share the first conductive line 110 or the second conductive line 120, while controlling the electrical access to one memory cell among the memory cells that are arrayed. To this end, the selector layer 140 may have a threshold switching characteristic of blocking the current or holding the current to practically no flow when the level of the voltage supplied to the upper and lower ends of the selector layer 140 is lower than a predetermined threshold voltage level. This means that below the threshold voltage the selector layer 140 hardly allows any current to flow, effectively blocking it. However, at a voltage level equal to or higher than the predetermined threshold voltage level, the selector layer 140 allows the current to flow freely. The selector layer 140 may be turned on at a voltage level equal to or higher than the threshold voltage level and turned off at a voltage level lower than the threshold voltage level.

Typically, the selector layer 140 may use a dielectric material into which a dopant is implanted. The dielectric material included in the selector layer 140 may include a silicon oxide layer or an amorphous silicon layer. The dopant doped into the selector layer 140 may include an N-type dopant or a P-type dopant, and the dopant may be implanted by an ion implantation process. The dopant may include, for example, one or more selected from the group including boron (B), nitrogen (N), carbon (C), phosphorus (P), arsenic (As), aluminum (Al), and germanium (Ge).

Typically, an oxide layer such as SiO₂ may be formed by mixing a source gas containing silicon (Si) and oxygen (O) by using a method, such as Chemical Vapor Deposition (CVD), Physical Vapor Deposition (PVD), or Atomic Layer Deposition (ALD). Since the deposited oxide layer formed in this manner has a relatively low density, when a dopant is subsequently implanted by an ion implantation process, there is an issue that micro voids are formed inside or damage may occur to a portion of the surface of the first electrode layer 130 disposed in the lower portion of the deposited oxide layer, making the interface between the selector layer 140 and the first electrode layer 130 unclear.

In the selector layer 140, strong scattering may occur due to the bonding of silicon (Si) and oxygen (O), and the possibility that a cluster is formed may be increased. Scattering refers to a phenomenon in which electrons change their direction or speed by interacting with other physical objects in a semiconductor material or device. Electron scattering may have a significant influence on determining the path that electrons move and determining the electrical characteristics. A cluster may refer to a group of atoms or molecules existing in a semiconductor material or structure. These clusters may have a significant influence on the characteristics of semiconductor devices, and often affect the performance or stability of the devices. Clusters may cause dispersion of key performance indicators (KPI) and may cause instability in the production process.

To solve this concern, in a preferred embodiment of the present disclosure, a buffer layer 131 including an amorphous silicon layer directly coupled to the upper or lower portion of the selector layer 140 and having one or more dopants selected from the group including group-13 elements, group-14 elements, and group-15 elements of the periodic table may be used. This may suppress the occurrence of clustering in the selector layer and reduce the dispersion of KPI.

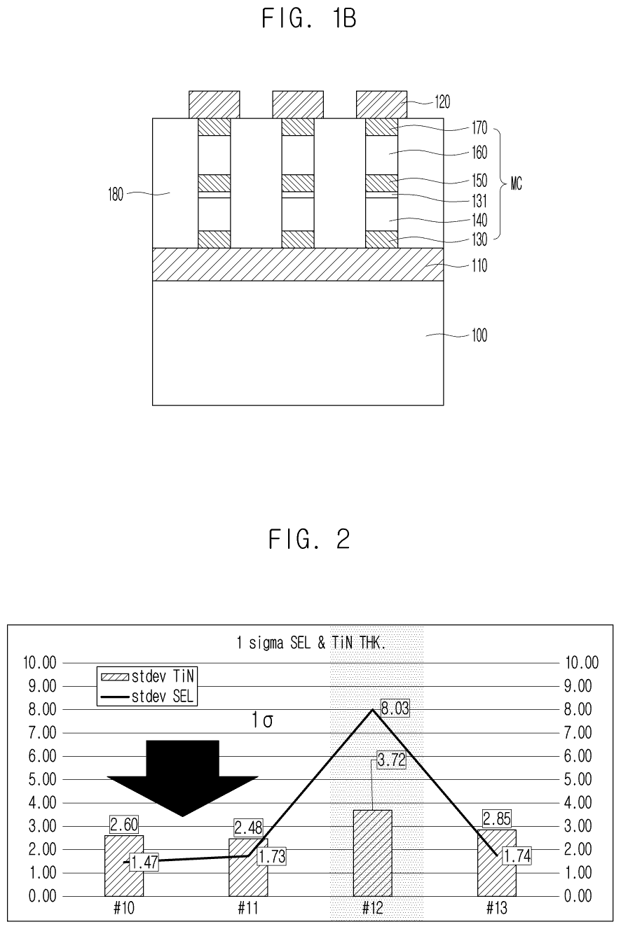

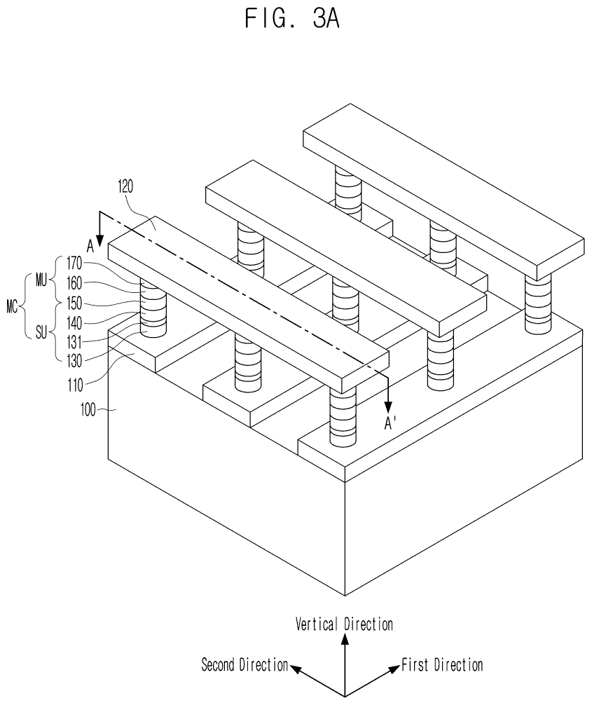

According to an embodiment of the present disclosure, the following advantages may be obtained compared to the comparative example. Herein, the comparative example corresponds to a case where a selector layer is formed by ion-implanting arsenic (As) into silicon oxide and there is no buffer layer. FIG. 2 is a graph showing the thickness dispersion of a selector having a 1-sigma arsenic (As)-doped silicon oxide and no buffer layer according to the comparative example, and the thickness dispersion of a selector in which a buffer layer having a 1-sigma boron (B)-doped amorphous silicon layer is disposed in the upper or lower portion of the selector according to the embodiment of the present disclosure. Sigma (σ) is an indicator of standard deviation used to measure the distribution of data in statistics. Therefore, 1 sigma may mean a range that is one standard deviation away from the mean value.

Here, #10 is Example 1 in which an oxide layer having a thickness of approximately 50 Å and a boron-doped amorphous silicon layer having a thickness of approximately 50 Å are sequentially deposited over a selector layer, and #11 is Example 2 in which a boron-doped amorphous silicon layer having a thickness of approximately 50 Å and an oxide layer having a thickness of approximately 50 Å are sequentially deposited over a selector layer. Also, #13 is Example 3 in which a boron-doped amorphous silicon layer having a thickness of approximately 100 Å is deposited over a selector layer, and #12 is a comparative example in which an oxide layer having a thickness of approximately 100 Å is deposited over a selector layer. As used herein, the term ‘approximately’ when referring to a numerical range means within +5% of the stated value. Here, all selector layers may have arsenic-doped silicon oxide layers. As illustrated in FIG. 2, whereas the thickness dispersion of the selector according to the comparative example without a buffer layer having a boron-doped amorphous silicon layer is approximately 8.03%, the thickness dispersions of the selectors according to Examples 1 to 3 in which the buffer layer having a boron-doped amorphous silicon layer is disposed over the selector are significantly low, which are approximately 1.47%, 1.73%, and 1.74%, respectively. This shows that the embodiment of the present disclosure may minimize the scattering and clustering of the selector and lower the thickness dispersion of the selector. The oxide layer disposed over the selector layer may preferably have a thickness of approximately 20 to 120 Å, and the buffer layer having the boron-doped amorphous silicon layer may preferably have a thickness of approximately 20 to 120 Å.

In the buffer layer according to an embodiment of the present disclosure, a conductive path may be formed in the vacancy of the lacking valence of 1 by doping amorphous silicon, which is a group-14 element of the periodic table, with a first dopant, which is a group-13 element of the periodic table; and conductivity may be given to the amorphous silicon layer to form a leaky path with similar conductivity by ion-implanting a second dopant, which is a group-14 element or a group-15 element of the periodic table. By disposing the buffer layer whose sheet resistance (Rp) value is different from the sheet resistance (Rp) value of the selector layer in the upper or lower portion of the selector layer, the scattering and clustering of the selector layer may be minimized when the second dopant with a large mass is ion-implanted, thereby forming a stable selector layer.

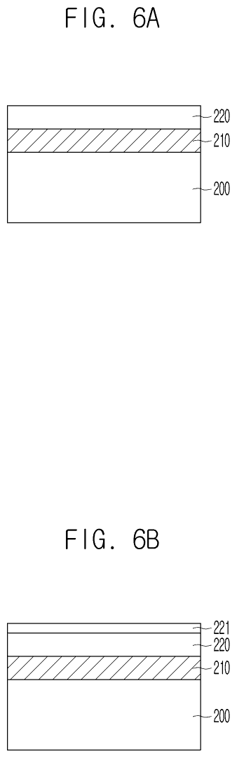

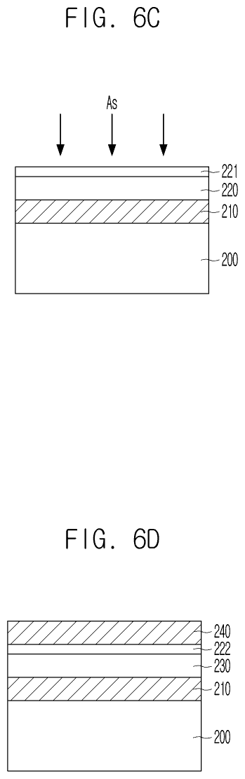

Referring back to FIGS. 1A and 1B, the buffer layer 131 may be disposed between the selector layer 140 and the second electrode layer 150. The buffer layer 131 may be formed as an initial buffer layer 221 partially remaining after the ion implantation process when the selector layer 140 is formed. The buffer layer 131 according to the embodiment of the present disclosure may correspond to a buffer layer 222 of FIG. 6D described below. The initial buffer layer 221 may function to prevent the formation of micro voids inside the selector layer 140 during the subsequent ion implantation process that is performed under the harsh conditions that a layer material cannot withstand, and to protect the first electrode layer 130. According to the embodiment of the present disclosure, a portion of the initial buffer layer 221 may remain after the ion implantation process without being absorbed into the selector layer 140, and it may be controlled to a level that does not affect the electrical characteristics. Therefore, it is possible to easily control the resistance of the memory cell MC as needed.

The thickness of the buffer layer 131 may be so thin that the buffer layer 131 does not affect the flow of current, that is, the buffer layer 131 may have a thickness that is not electrically significant. For example, the thickness of the buffer layer 131 may be in the range of approximately 20 Å to 120 Å.

The buffer layer 131 may use a dielectric material into which a dopant is implanted. According to a preferred embodiment of the present disclosure, the buffer layer 131 may include an amorphous silicon layer that is doped with boron (B). According to yet another embodiment of the present disclosure, the buffer layer 131 may be doped with arsenic (As) by additional ion implantation into the boron-doped amorphous silicon layer.

According to the embodiments of the present disclosure, the dopant doped into the amorphous silicon layer may be a group-13 element of the periodic table instead of boron (B), and may be a group-14 element or a group-15 element of the periodic table instead of arsenic (As).

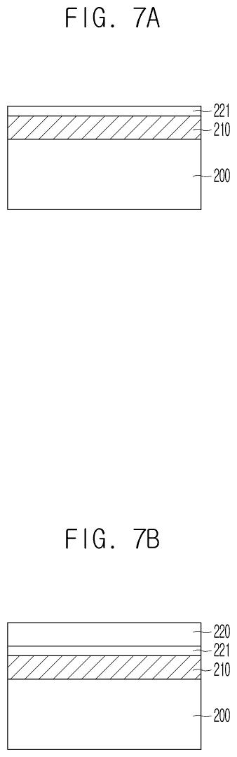

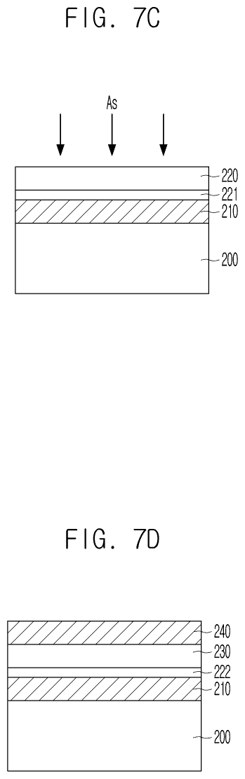

The formation of the buffer layer 131 will be described in detail later with reference to FIGS. 6A to 7D.

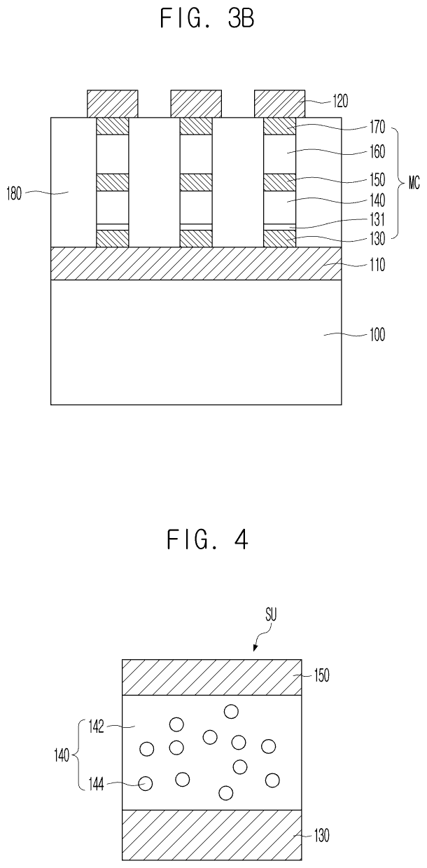

FIGS. 3A and 3B illustrate a semiconductor device in accordance with another embodiment of the present disclosure. FIG. 3A shows a perspective view, and FIG. 3B shows a cross-sectional view taken along a line A-A′ shown in FIG. 3A. The semiconductor memory in accordance with the embodiment of the present disclosure may have a structure in which the buffer layer 131 is formed in the lower portion of the selector layer 140. The semiconductor device illustrated in FIGS. 3A and 3B is similar to the semiconductor device illustrated in FIGS. 1A and 1B except that the buffer layer 131 is formed in the lower portion of the selector layer 140. As for what is similar to the embodiment of the present disclosure illustrated in FIGS. 1A and 1B, a detailed description of it will be omitted herein.

Referring to FIGS. 3A and 3B, the buffer layer 131 may be interposed between the first electrode layer 130 and the selector layer 140. The buffer layer 131 may be formed as the initial buffer layer 221 partially remains after the ion implantation process when the selector layer 140 is formed. In other words, the buffer layer 131 according to the embodiment of the present invention may correspond to the buffer layer 222 illustrated in FIG. 7D, which will be described below. According to the embodiment of the present disclosure, a portion of the initial buffer layer 221 may remain after the ion implantation process without being absorbed into the selector layer 140, but it may be controlled to a level that does not affect the electrical characteristics. Therefore, it is possible to easily control the resistance of the memory cell MC as needed.

According to an embodiment of the present disclosure, a structure in which the buffer layer 131 is formed in the lower portion of the selector layer 140 may be realized. In the amorphous silicon layer having the first dopant, silicon (Si) may form a bond between hydrogen (H) and the first dopant, and the second dopant may be absorbed into the vacancy between them, preventing the scattering of the selector layer. The second dopant may be absorbed into the vacancy of the amorphous silicon layer of the buffer layer 131 not only in the structure where the buffer layer 131 is formed in the upper portion of the selector layer 140 but also in the structure where the buffer layer 131 is formed in the lower portion of the selector layer 140. Therefore, even in the embodiment of the present disclosure, all advantages described in the above-described embodiment of the present disclosure may be obtained.

Although the memory cells MC in FIGS. 1A, 1B, 3A, and 3B show a stacked structure of the first electrode layer 130, the selector layer 140, the second electrode layer 150, the memory layer 160, and the third electrode layer 170, the concept and spirit of the present invention are not limited thereto, and the layer structure of the memory cell MC may be diversely modified. For example, at least one among the first electrode layer 130, the second electrode layer 150, and the third electrode layer 170 may be omitted. For example, the memory cell MC may include the selector layer 140, the first electrode layer 130 disposed below the selector layer 140, and the third electrode layer 170 disposed over the selector layer 140. For example, the first electrode layer 130 disposed below the selector layer 140 may include titanium nitride (TIN), and the third electrode layer 170 disposed over the selector layer 140 may include a carbon (C) electrode. Also, for another embodiment, the upper and lower positions of the selector layer 140 and the memory layer 160 may be switched with each other. Also, for yet another embodiment, the memory cell MC may further include one or more layers (not shown) to improve the characteristics or to improve the process.

FIG. 4 is a cross-sectional view illustrating a structure of a selector unit SU in accordance with an embodiment of the present disclosure.

Referring to FIG. 4, the selector unit SU may include a first electrode layer 130, a selector layer 140, and a second electrode layer 150.

As described above, the first electrode layer 130 and the second electrode layer 150 may include diverse conductive materials such as metals, metal nitrides, and the like. The first electrode layer 130 and the second electrode layer 150 may be formed of the same material so as to have the same work function. For example, the first electrode layer 130 and the second electrode layer 150 may include titanium nitride (TiN) having a work function of approximately 4.4 to 4.6 eV. However, the technical concepts and scope of the present disclosure are not limited thereto, and the first electrode layer 130 and the second electrode layer 150 may be formed of different materials so as to have different work functions.

The selector layer 140 may include an amorphous silicon layer 142 and a dopant 144 which is implanted into the amorphous silicon layer 142.

The amorphous silicon layer 142 may be a dielectric material having a relatively wide band gap, for example, a dielectric material having a band gap of approximately 5.0 eV or more. For example, there may be a deep trap whose energy level is closer to an energy level of a valence band than to an energy level of a conduction band of a thin layer in the amorphous silicon layer 142. The dopant 144 may function to form a shallow trap that provides a path for conductive carriers, for example, electrons or holes, to move in the amorphous silicon layer 142. The shallow trap may have an energy level which is closer to the energy level of the conduction band than to the energy level of the valence band of the amorphous silicon layer 142.

The dopant 144 may include one or more selected from the group including group-13 elements, group-14 elements, and group-15 elements of the periodic table having different valences than that of silicon (Si).

For example, the dopant 144 may include the group-13 elements of the periodic table, such as boron (B), aluminum (Al), gallium (Ga), or indium (In). For example, the dopant 144 may include a group-14 element of the periodic table, such as carbon (C), silicon (Si), germanium (Ge), or tin (Sn), together with a group-13 element of the periodic table. For example, the dopant 144 may include a group-15 element of the periodic table, such as nitrogen (N), phosphorus (P), arsenic (As), or antimony (Sb), together with a group-13 element of the periodic table. For example, the dopant 144 may include boron (B), and the dopant 144 may further include one or more of phosphorus (P) and arsenic (As) together with boron (B).

The concentration of the dopant and the ratio of amorphous silicon in the doped amorphous silicon layer may vary greatly according to the process conditions. The concentration of the dopant may be controlled by controlling the flow rates and hydraulic pressures of diborane (B₂H₆) and silane gas (SiₓH_{y}). For example, increasing the flow rate of diborane may increase the concentration of the dopant, and conversely, increasing the flow rate of silane gas may increase the ratio of amorphous silicon. When the doped amorphous silicon layer is generated by reacting diborane with silane gas under the temperature condition of approximately 300° C., the dopant 144 may have a concentration of approximately 10 to 30 wt %, and the amorphous silicon may have a concentration of approximately 90 to 70 wt % in the doped amorphous silicon layer. When the doped amorphous silicon layer is formed by reacting diborane with silane gas under the temperature condition of approximately 400° C., the diffusion of the dopant may become more active so that the amorphous silicon layer may be doped with the dopant more easily. Accordingly, in this case, in the doped amorphous silicon layer, the dopant 144 may have a concentration of approximately 30 to 90 wt %, and the amorphous silicon may have a concentration of approximately 70 to 10 wt %.

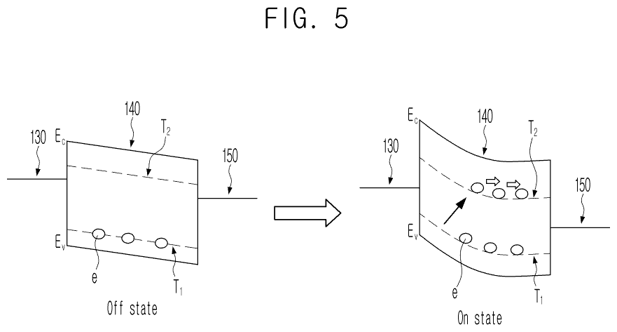

FIG. 5 illustrates an operation of the selector unit SU shown in FIG. 4.

Referring to FIG. 5, in an off state where no voltage is applied to the selector layer 140, a conductive carrier, for example, an electron (e), may be trapped in a deep trap T1 of the selector layer 140.

When a voltage equal to or higher than the threshold voltage level is applied to the selector layer 140 of the off state through the first electrode layer 130 and the second electrode layer 150, an on state in which current flows through the selector layer 140 may be realized. To be specific, when a voltage equal to or higher than the threshold voltage level is applied to the selector layer 140, the conductive carriers trapped in the deep trap T1 may jump into a shallow trap T2 by a thermal emission process or a tunneling process, and the conductive carriers may move through the shallow trap T2 to create a conductive path that couples the first electrode layer 130 and the second electrode layer 150.

When the voltage applied to the selector layer 140 of the on state is decreased, the number of the conductive carriers moving from the deep trap T1 to the shallow trap T2 may also be decreased, so that the selector layer 140 may be turned off again.

In this way, the selector layer 140 may be turned on and off.

FIGS. 6A to 6C illustrate a method for fabricating a semiconductor device in accordance with an embodiment of the present disclosure.

Referring to FIG. 6A, a substrate 200 where a predetermined lower structure is formed may be provided. The substrate 200 may include required diverse circuits. For example, the substrate 200 may include a conductive line which is similar to the first conductive line 110 of FIGS. 1A and 3A described above.

Subsequently, a first electrode layer 210 may be formed over the substrate 200. The first electrode layer 210 may be realized as a TiN thin layer. A TiN thin layer, as used herein, refers to a layer having a thickness of 5 nm to 100 nm, or more specifically, 5 nm to 50 nm.

Subsequently, an initial selector layer 220 may be formed over the first electrode layer 210. The initial selector layer 220 may include a silicon oxide layer or an amorphous silicon layer that is doped with a dopant as a silicon (Si)-containing layer. Here, the method for forming the silicon oxide layer or the amorphous silicon layer that is doped with a dopant may be realized as a method of depositing a silicon oxide layer or an amorphous silicon layer that is doped with a dopant. The dopant may include at least one selected from the group including boron (B), nitrogen (N), carbon (C), phosphorus (P), arsenic (As), aluminum (Al), and germanium (Ge).

Subsequently, referring to FIG. 6B, initial buffer layer 221 may be formed over the initial selector layer 220. Subsequently, an amorphous silicon layer doped with a dopant may be formed as the initial buffer layer 221 over the initial selector layer 220. Here, the method for forming the amorphous silicon layer that is doped with a dopant may be realized as a method of depositing an amorphous silicon layer that is doped with a first dopant. The first dopant may be a group-13 element of the periodic table, such as boron (B), aluminum (Al), gallium (Ga), or indium (In). Preferably, the first dopant may be boron (B).

The amorphous silicon layer having the first dopant may be formed by a Low-Pressure Chemical Vapor Deposition (LPCVD) process using a first dopant-containing catalyst and a silicon source gas. For example, the amorphous silicon layer having the first dopant may be formed by a Low-Pressure Chemical Vapor Deposition (LPCVD) process using silane gas (SiₓH_{y}), for example, SiH₄, and diborane (B₂H₆). The Low-pressure chemical vapor deposition process may provide a uniform thin layer and a low defect rate, thereby improving the performance of a semiconductor device.

When boron (B) is applied as the first dopant, a boron-containing catalyst may be selected from the group including trimethyl borate (B(Ome)₃), boron trichloride (BCl₃), boron tribromide (BBr₃), boron dibromide (BBr₂), boron trifluoride (BF₃), or diborane (B₂H₆). In the case of a boron (B)-containing catalyst that does not contain hydrogen in itself, it may be supplied together with hydrogen (H₂).

Subsequently, referring to FIG. 6C, a second dopant, for example, arsenic (As), may be ion-implanted into the amorphous silicon layer having the first dopant. In addition to arsenic (As), the second dopant may include a group-14 element of the periodic table, such as carbon (C), silicon (Si), germanium (Ge), or tin (Sn), or a group-15 element of the periodic table, such as nitrogen (N), phosphorus (P), or antimony (Sb). Preferably, the first dopant may include boron (B), and the second dopant may include at least one selected from the group including carbon (C), silicon (Si), germanium (Ge), phosphorus (P), and arsenic (As). The ion implantation of the second dopant may be performed in a direction substantially perpendicular to the surface of the substrate 200, and an angled ion-implantation may also be performed. Also, the ion implantation may be performed repeatedly several times. Electrical characteristics may be given to a fabricated semiconductor device by ion-implanting the second dopant, such as arsenic (As), into the amorphous silicon layer. The characteristics of the semiconductor device may be appropriately changed by changing the concentration of the ion-implanted second dopant. For example, the concentration of the ion-implanted second dopant may be adjusted in a range of approximately 10% to 50% according to the implantation conditions.

An amorphous silicon layer into which the second dopant is additionally ion-implanted may be easily secured, and a conductive path in the amorphous silicon layer may be easily secured due to the second dopant impact during the ion-implantation process.

This ion implantation process may be performed by high energy and a high ion implantation amount, and since the ions such as arsenic (As) are heavy components having a large mass, the ion implantation process may be performed under conditions that the layer material hardly withstands. According to the embodiment of the present disclosure, the second dopant may be absorbed into the vacancy between silicon (Si) and hydrogen (H) in the amorphous silicon layer including the first dopant. Therefore, the layer material may be able to withstand such harsh conditions during the ion implantation process. This may prevent defects such as micro voids from being formed inside. Also, since the initial buffer layer 221 serves as a buffer, damage to the first electrode layer 210 may be minimized. The initial buffer layer 221 that serves as a buffer may be entirely removed during the ion implantation process and absorbed into the selector layer 230. After the ion implantation process is completed, the initial buffer layer 221 may not exist.

The buffer layer 222 may be formed as a portion of the initial buffer layer 221 that remains after the ion implantation process during the formation of the selector layer 230. Subsequently, referring to FIG. 6D, a second electrode layer 240 may be formed over the buffer layer 222. The second electrode layer 240 may be formed by depositing a conductive material. The second electrode layer 240 may be realized as a TiN single thin layer, or the second electrode layer 240 may also be realized by stacking a carbon (C) thin layer and a TiN layer. Herein, the carbon (C) thin layer may be formed at the interface between the amorphous silicon layer and the TIN layer.

The semiconductor device in accordance with an embodiment of the present disclosure may be fabricated by the process described above.

Referring back to FIG. 6D, the semiconductor device in accordance with an embodiment of the present disclosure may include the substrate 200, the first electrode layer 210 over the substrate 200, and the selector layer 230, the buffer layer 222 and the second electrode layer 240 that are sequentially formed over the first electrode layer 210.

FIGS. 7A to 7D illustrate a method for fabricating a semiconductor device in accordance with another embodiment of the present disclosure. Through the fabrication method according to the embodiment of the present disclosure, a semiconductor memory having a structure in which the buffer layer 131 is formed in the lower portion of the selector layer 140 may be fabricated. The method for fabricating the semiconductor device illustrated in FIGS. 7A to 7D is similar to the method for fabricating the semiconductor device shown in FIGS. 6A to 6D except that the buffer layer 131 is formed in the lower portion of the selector layer 140. As for what is similar to the embodiment of the present disclosure illustrated in FIGS. 6A to 6D, a detailed description of it will be omitted herein.

Referring to FIG. 7A, an amorphous silicon layer doped with a first dopant may be formed as an initial buffer layer 221 over a first electrode layer 210.

Subsequently, referring to FIGS. 7B and 7C, an initial selector layer 220 may be formed over the initial buffer layer 221, and a second dopant, for example, arsenic (As), may be ion-implanted into the upper portion of the initial selector layer 220.

According to an embodiment of the present disclosure, even though the initial buffer layer 221 is disposed below the initial selector layer 220, the initial buffer layer 221 may serve as a buffer when the second dopant is ion-implanted. The initial buffer layer 221 that serves as a buffer may be entirely removed during the ion implantation process and absorbed into the selector layer 230. After the ion implantation process is completed, the initial buffer layer 221 may not exist.

Subsequently, referring to FIG. 7D, a second electrode layer 240 may be formed over the ion-implanted selector layer 230.

The semiconductor device in accordance with an embodiment of the present disclosure may be fabricated by the process described above.

Referring back to FIG. 7D, the semiconductor device in accordance with an embodiment of the present disclosure may include a substrate 200, a first electrode layer 210 over the substrate 200, and a buffer layer 222, a selector layer 230 and a second electrode layer 240 that are sequentially formed over the first electrode layer 210.

According to an embodiment of the present disclosure, by minimizing the scattering that may be caused by the metal ions ion-implanted into the selector layer during an ion implantation process, the selector characteristics of a memory cell may be improved and the damage to a lower electrode may be reduced.

While the embodiments of the present disclosure have been described with respect to specific embodiments, it will be apparent to those skilled in the art that various changes and modifications may be made without departing from the technical concepts and scope of the disclosure as defined in the following claims. Furthermore, the embodiments may be combined to form additional embodiments.

What is claimed is:

1. A semiconductor device comprising:
a plurality of memory cells,
wherein each of the memory cells includes:
a memory layer;
a selector layer formed in an upper or lower portion of the memory layer to select the memory layer; and
a buffer layer directly coupled to an upper or lower portion of the selector layer, wherein the buffer layer includes an amorphous silicon layer including at least one dopant selected from a group including group-13 elements, group-14 elements, and group-15 elements of the periodic table.

2. The semiconductor device of claim 1, wherein the dopant includes a group-13 element of the periodic table.

3. The semiconductor device of claim 1, wherein the dopant includes a group-13 element and a group-14 element of the periodic table.

4. The semiconductor device of claim 1, wherein the dopant includes a group-13 element and a group-15 element of the periodic table.

5. The semiconductor device of claim 1, wherein the dopant includes boron (B).

6. The semiconductor device of claim 1, wherein the dopant includes at least one of phosphorus (P) and arsenic (As), and boron (B).

7. The semiconductor device of claim 1, wherein the dopant includes at least one selected from a group including carbon (C), silicon (Si), and germanium (Ge), and boron (B).

8. The semiconductor device of claim 1, wherein the dopant has a concentration of approximately 10 to 30 wt % in the doped amorphous silicon layer.

9. The semiconductor device of claim 1, wherein the memory cell further includes
a first electrode layer disposed below the selector layer, and
a second electrode layer disposed over the selector layer.

10. The semiconductor device of claim 9, wherein the first and second electrodes include a TiN thin layer.

11. The semiconductor device of claim 9, further comprising:
a SiN thin layer at an interface between the first electrode layer and the selector layer, and
a carbon (C) thin layer at an interface between the selector layer and the second electrode layer.

12. The semiconductor device of claim 1, wherein the buffer layer has a thickness of approximately 20 Å to 120 Å.

13. A method for fabricating a semiconductor device including a plurality of memory cells, the method comprising:
forming a selector layer; and
forming an amorphous silicon layer including a dopant as a buffer layer in an upper or lower portion of the selector layer,
wherein the buffer layer includes an amorphous silicon layer including at least one dopant selected from a group including group-13 elements, group-14 elements, and group-15 elements of periodic table.

14. The method of claim 13, wherein forming the amorphous silicon layer includes
depositing an amorphous silicon layer that is doped with a first dopant.

15. The method of claim 14, wherein the first dopant has a concentration of approximately 10 to 30 wt % in the doped amorphous silicon layer.

16. The method of claim 13, further comprising
forming an electrode layer over the selector layer.

17. The method of claim 13, wherein forming the amorphous silicon layer includes:
depositing an amorphous silicon layer that is doped with a first dopant; and
ion-implanting a second dopant into the amorphous silicon layer that is doped with the first dopant.

18. The method of claim 13, wherein the first dopant includes a group-13 element of the periodic table, and
the second dopant includes a group-14 element or a group-15 element of the periodic table.

19. The method of claim 13, wherein the first dopant includes boron (B), and
the second dopant includes at least one selected from a group including carbon (C), silicon (Si), germanium (Ge), phosphorus (P), and arsenic (As).

20. The method of claim 14, wherein depositing the amorphous silicon layer that is doped with the first dopant is performed by a Low-Pressure Chemical Vapor Deposition (LPCVD) process using SiH₄ and diborane (B₂H₆).

21. The method of claim 13, wherein the buffer layer has a thickness of approximately 20 Å to 120 Å.
